(19) United States
(12) Patent Application Publication
(10) Pub. No.: US 2008/0128907 A1
(43) Pub. Date: Jun. 5, 2008

(54) SEMICONDUCTOR STRUCTURE WITH LINER

(75) Inventors: Chih-Chao Yang, Poughkeepsie, NY (US); Ping-Chuan Wang, Hopewell Junction, NY (US)

Correspondence Address: GREENBLUM & BERNSTEIN, P.L.C., 1950 ROLAND CLARKE PLACE, RESTON, VA, 20191, US

(73) Assignee: INTERNATIONAL BUSINESS MACHINES CORPORATION, Armonk, NY (US)

(21) Appl. No.: 11/565,810

(22) Filed: Dec. 1, 2006

(51) Int. Cl. H01L 23/52; H01L 21/4763

(52) U.S. Cl. 257/751; 438/643; 257/E23.141; 257/E21.495

(57) ABSTRACT

A semiconductor structure and methods of making the same. The semiconductor structure includes an interconnect feature substantially filled with a conductive material and disposed within a first dielectric material, and a second dielectric material comprising a contact via over the interconnect feature. The semiconductor structure further includes a gouging feature in the conductive material and adjacent to the contact via, and a first liner material deposited substantially only on surfaces of the conductive material in the gouging feature.

### FIELD OF THE INVENTION

The invention generally relates to integrated circuit design and fabrication and, more particularly, to a semiconductor structure having a gouging feature and a liner and methods of making the same.

### BACKGROUND OF THE INVENTION

Semiconductor devices generally include a plurality of circuits which form an integrated circuit fabricated on a semiconductor substrate. A network of signal paths is normally routed to connect the circuit elements distributed on the surface of the substrate. Efficient routing of these signals across the device requires formation of multilevel or multilayered schemes, such as, for example, single or dual damascene wiring structures. Within a typical network of signal paths, metal vias (e.g., studs) run substantially perpendicular to the semiconductor substrate and metal lines (e.g., wires) run substantially parallel to the semiconductor substrate.

As the wiring density of semiconductor devices increases, the quality of the metal wirings and studs becomes increasingly important to ensure adequate yield and reliability. However, current processes for embedding submicron-scale metal studs and wires in low k (dielectric constant) dielectric materials result in structures having poor mechanical integrity, which can lead to unsatisfactory thermal cycling and stress migration resistance in interconnect structures. The problem is compounded when porous low k dielectric materials are used.

To address this poor mechanical strength issue while employing copper damascene and low k dielectric material in an interconnect structure, a “via punch through” technique has been used in the art. The via-punch through, as is known to those having ordinary skill in the art, provides a gouging feature (e.g., anchoring area) within the interconnect area that provides a reasonable contact resistance as well as increased mechanical strength of the contact stud. However, known processes for creating the gouging feature, such as Argon sputtering, damage existing liners and/or low k dielectric material in the vicinity of the features (e.g., wires, gouges, etc.). Moreover, the damage impact of Argon sputtering is much higher on porous ultra-low k dielectric materials (e.g., dielectric materials having a dielectric constant, k, of about 2.8 or less). Such damage results in liner damage and/or a roughening of the dielectric material at the base of features (e.g., wires, gouges, etc.), which can result in poor dielectric breakdown strength and/or poor electromigration resistance. Therefore, such damage represents a considerable yield detractor and reliability concern for advanced chip manufacturing.

Accordingly, there exists a need in the art to overcome the deficiencies and limitations described hereinabove.

### SUMMARY OF THE INVENTION

In a first aspect of the invention, there is a semiconductor structure comprising an interconnect feature substantially filled with a conductive material and disposed within a first dielectric material, and a second dielectric material comprising a contact via over the interconnect feature. The semiconductor structure further includes a gouging feature in the conductive material and adjacent to the contact via, and a first liner material deposited substantially only on surfaces of the conductive material in the gouging feature.

In a second aspect of the invention, there is a semiconductor structure comprising an interconnect feature substantially filled with a conductive material and disposed within a first dielectric material, and a second dielectric material comprising a contact via over the interconnect feature. The semiconductor structure further comprises a gouging feature in the conductive material and adjacent to the contact via, and a copper seed layer over the gouging feature.

In a third aspect of the invention, there is a method comprising forming a dielectric material comprising a contact via over a conductive material of an interconnect feature, forming a gouging feature in the conductive material and adjacent to the contact via, and selectively depositing a first liner material substantially only on exposed surfaces of the conductive material in the gouging feature.

### BRIEF DESCRIPTION OF THE DRAWINGS

FIGS. 1 through 7 show a method of making a beginning semiconductor structure according to aspects of the invention;

FIGS. 8A and 8B show a method of making a first semiconductor structure according to aspects of the invention;

FIGS. 9A and 9B show a method of making a second semiconductor structure according to aspects of the invention;

FIGS. 10A and 10B show a method of making a third semiconductor structure according to aspects of the invention;

FIGS. 11A and 11B show a method of making a fourth semiconductor structure according to aspects of the invention; and

FIGS. 12 and 13 show comparisons or prior art structures to structures produced according to aspects of the invention.

### DETAILED DESCRIPTION OF EMBODIMENTS OF THE INVENTION

The invention is directed to semiconductor devices and methods of making the same. The inventive methods avoid damaging dielectric material and/or liners during sputtering. The inventive devices thus have improved interconnect structures, such that the dielectric breakdown strength and/or the electromigration resistance of devices is improved.

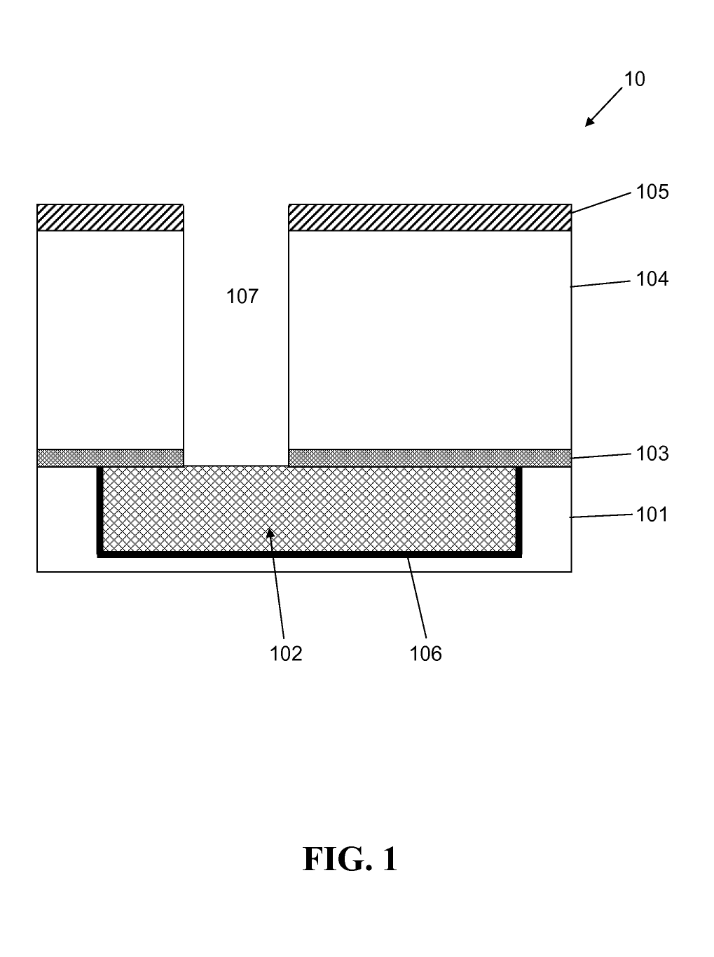

The process flow of the present invention begins with providing the initial structure 10 shown in FIG. 1. In embodiments, the structure 10 comprises a multilevel interconnect including a first dielectric material layer 101 containing an interconnect feature 102. A capping layer 103 is provided over the first dielectric layer 101 and interconnect feature 102, and a second dielectric layer 104 is disposed over the capping layer 103. A hardmask 105 is further provided over the second dielectric layer 104. A diffusion barrier (e.g., liner) 106 is disposed between the first dielectric layer 101 and the interconnect feature 102. Lastly, within the structure 10 is a contact via 107 that extends through the hardmask 105, the second dielectric layer 104, and the capping layer 103, to the interconnect feature 102. The contact via 107 will be used as a stud or contact feature, as described below.

The structure 10 as thus described can be made using conventional techniques known to those of skill in the art. For example, the structure 10 may be formed by applying the first dielectric layer 101 to a surface of a substrate (not shown). The substrate may comprise a semiconductor material, an insulating material, a conductive material, or any combination thereof. When the substrate is comprised of a semiconductor material, any semiconductor material may be used, such as, for example, Si, SiGe, SiGeC, SiC, GE alloys, GaAs, InAs, InP, and other III/V or II/VI compound semiconductors. Moreover, the present invention also contemplates cases in which the substrate is a layered semiconductor, such as, for example, Si/SiGe, Si/SiC, silicon-on-insulator (SOI), or silicon germanium-on-insulator (SGOI).

When the substrate is an insulating material, the insulating material can be an organic insulator, an inorganic insulator, or a combination thereof. When the substrate is a conducting material, the substrate may include, for example, polysilicon, elemental metal, alloys of elemental metals, metal silicide, metal nitride, or combinations thereof. When the semiconductor comprises a semiconductor material, one or more semiconductor devices, such as, for example, complementary metal oxide semiconductor (CMOS) devices can be fabricated thereon.

The first dielectric material 101 may comprise any interlevel or intralevel dielectric, and may be porous or non-porous. Suitable materials include, but are not limited to, SiO₂, Si₃N₄, SiCOH, silsesquioxanes, C doped oxides (i.e., organosilicates) that include atoms of Si, C, O, and/or H, thermosetting polyarylene ethers, SiLK (a polyarylene ether available from Dow Chemical Corporation), JSR (a spin-on silicon-carbon contained polymer material available from JSR Corporation), etc., or layers thereof. The term “polyarylene” is used in this application to denote moieties or inertly substituted aryl moieties which are linked together by bonds, fused rings, or inert linking groups, such as, for example, oxygen, sulfur, sulfone, sulfoxide, carbonyl, and the like. In embodiments, the first dielectric material 101 has a dielectric constant, k, of about 4.0 or less, and has a thickness in the range of about 200 nm to 450 nm. It is understood, however, that other materials having a different dielectric constant and/or thickness may be employed within the scope of the invention.

Still referring to FIG. 1, in embodiments, the interconnect feature 102 and barrier layer 106 are formed by conventional lithography processes. For example, a photoresist is applied to the surface of the first dielectric material 101, the photoresist is exposed to a desired pattern of radiation, and the exposed resist is etched utilizing a conventional resist developer. Then, an opening is etched in the first dielectric material 101, and filled with the barrier layer 106 and a conductive material of the interconnect feature 102. The barrier layer 106 may comprise, for example, Ta, TaN, Ti, TiN, Ru, RuN, W, WN, or any other material that can serve as a barrier to prevent conductive material from diffusing therethrough. In embodiments, the barrier layer 106 has a thickness in the range of about 4 nm to 40 nm. The conductive material of the interconnect feature 102 may comprise any suitable known material, such as, for example, Cu, W, Al, Cu alloys, etc.

After forming the interconnect feature 102, the capping layer 103 is formed using a conventional deposition process, such as, for example, chemical vapor deposition (CVD), atomic layer deposition (ALD), physical vapor deposition (PVD), plasma enhanced chemical vapor deposition (PECVD), etc. The capping layer 103 may comprise, for example, SiC, Si₃N₄, SiO₂, SiC(N,H) (i.e., nitrogen or hydrogen doped silicon carbide), etc., and may have a thickness in the range of about 15 nm to 55 nm.

The second dielectric material 104 is applied to the upper exposed surface of the capping layer 103. The second dielectric material 104 may comprise the same or different dielectric material as that of the first dielectric material 101. Moreover, the processing techniques and thickness ranges described above with respect to the first dielectric material 101 are also applicable to the second dielectric material 104.

The contact via 107 is formed by forming the hardmask 105 on the upper surface of the second dielectric material 104. The hardmask 105 may include, for example, oxide, nitride, oxynitride, or any suitable combination thereof. In embodiments, the hardmask 105 comprises one of SiO₂ and Si₃N₄ and has a thickness of about 10 nm to 80 nm. The hardmask 105 may be formed using a conventional deposition process, such as, for example, CVD, PECVD, chemical solution deposition, etc.

After forming the hardmask 105, the contact via 107 is formed using any suitable conventional process, such as, for example, lithography and etching. The width of the contact via 107 is defined during this step.

Although materials and thicknesses for the various layers (101, 102, 103, 104, 105, 106) have been described, it is understood that other suitable materials and thicknesses may be employed within the scope of the invention.

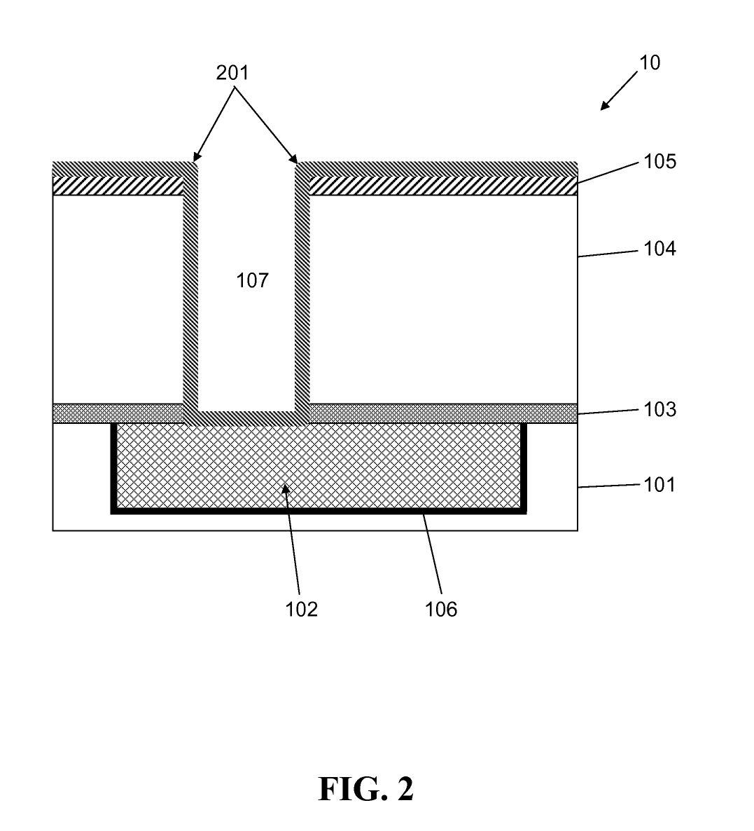

As depicted in FIG. 2, a diffusion barrier layer 201 is deposited over the exposed surfaces of the structure 10. The diffusion barrier layer 201 covers the exposed surfaces of the hardmask 105, the sidewalls of the second dielectric material 104 within the contact via 107, and the exposed portion of the interconnect feature 102. The diffusion barrier layer 201 may comprise metals, such as, for example, TaN, Ta, Ti, TiN, RuTa, RuTaN, W, Ru, I, etc. Alternatively, the diffusion barrier layer 201 may comprise an insulator material, such as, for example, SiO₂, Si₃N₄, SiC, SiC(N, H). The diffusion barrier layer 201 may be deposited in any known manner, including PVD, CVD, AVD, spin-on coating, etc. In embodiments, the layer 201 has a thickness in the range of about 0.5 nm to 20 nm.

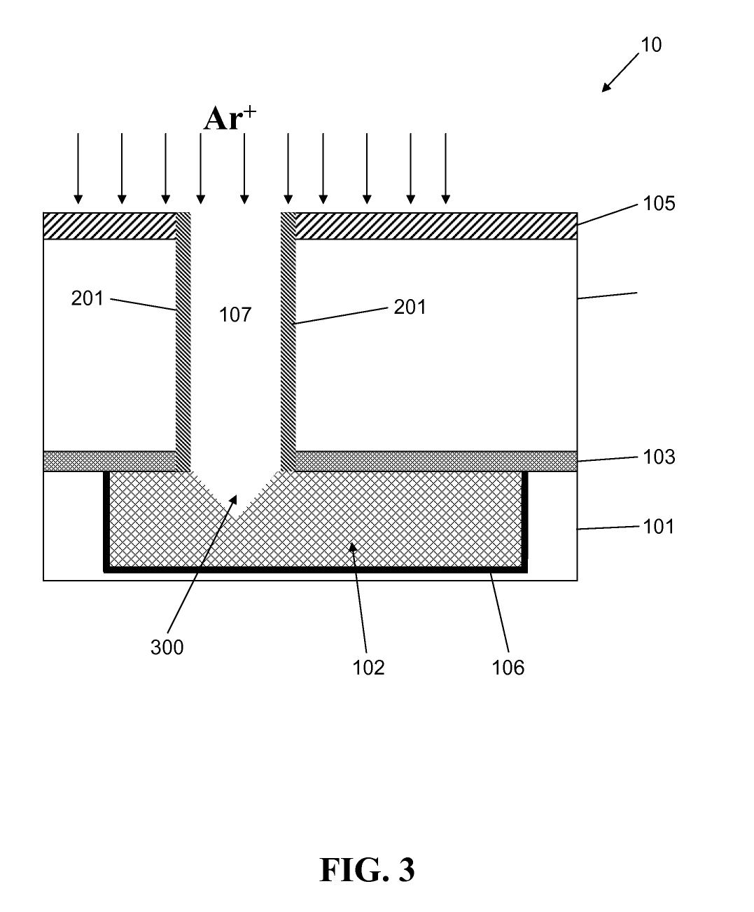

As shown in FIG. 3, following formation of the diffusion barrier layer 201, the structure 10 is subjected to a gaseous sputtering process. The gas used in the sputtering process may comprise one of Ar, He, Ne, Xe, N₂, H₂, NH₃, N₂H₂, or mixtures thereof, and preferably comprises Ar. The sputtering process removes the diffusion barrier layer 201 material from the bottom of the contact via 107 and punches through the conductive material of the interconnect feature 102 to create a gouging feature (e.g., anchoring area) 300. The sputtering process also removes the diffusion barrier layer 201 material that is located on the horizontal surfaces of the hardmask 105. Advantageously, the second dielectric material 104 is not damaged during the sputtering because it is protected by the hardmask 105.

The sputtering process used in forming the gouging feature 300 comprises any conventional sputtering process that is typically used in interconnect technology to form such a feature. For example, gaseous sputtering can be performed using the following non-limiting conditions: Ar gas flow of about 20 sccm, temperature of about 25° C., bias of top electrode of about 400 KHz and about 750 W, table bias of about 13.6 MHz and about 400 W, and a process pressure of about 0.6 mtorr.

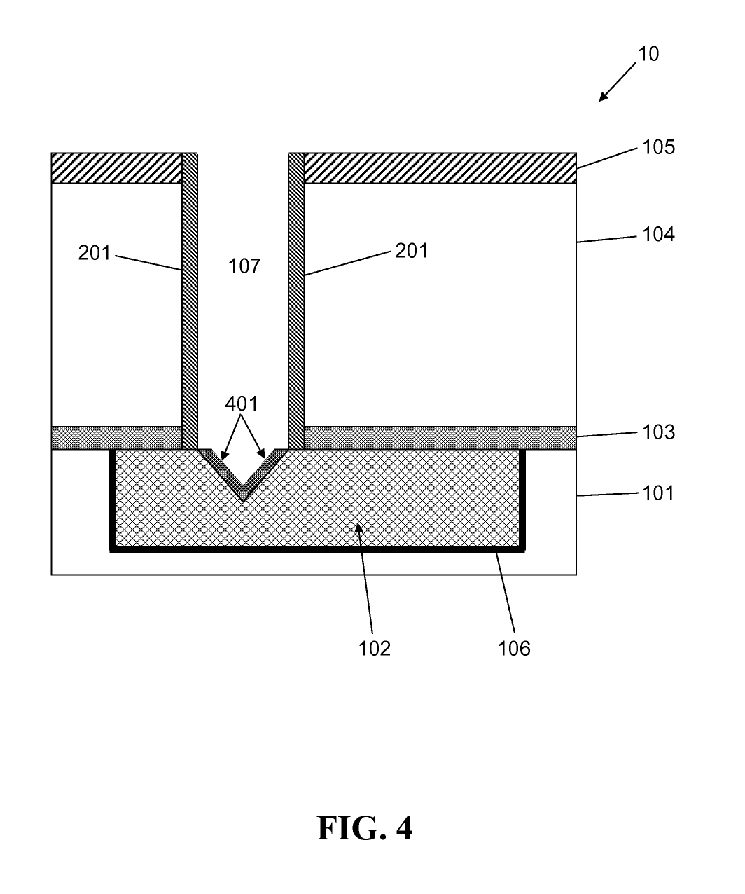

FIG. 4 shows liner 401 that is deposited in the gouging feature 300 after the sputtering process. In embodiments, the liner 401 has a thickness of about 2 nm to 10 nm, although other thicknesses may be used. The liner 401 is deposited on the exposed surfaces of the conductive material of the gouging feature 300 by a selective deposition process.

Deposited liner 401 may be composed of any suitable metallic capping material including, but not limited to, Ta, Ru and Co-containing materials. The term “Co-containing materials” is used herein to denote elemental Co alone or elemental Co and at least one of P, B, W, Mo, and Re. For example, the liner 401 may comprise Co, CoP, COWP, CoB or COWP, with CoP or COWP being preferred.

In embodiments, the liner 401 is formed by a selective deposition process such as, for example, an electroless plating process in which a redox reaction involving the oxidation of one or more soluble reducing agent(s) and the reduction of one or more metallic ions occurs on the surface of a substrate. For many metals including Cu, Ni, Co, Au, Ag Pd, Rh, Pt, the freshly deposited surface is sufficiently catalytic for the process to continue.

In embodiments, the electroless plating process employs a hypophosphite reducing agent. For example, a mixture of hypophosphite ions and cobalt ions is made together with citrate stabilizing agent, at a suitable pH and temperature (usually between about 650 to 75° C.). When an activated catalyzed substrate, as described above, is immersed on this plating bath, the following reaction occurs on the substrate:

Co²⁺+2H₂PO₂⁻→Co metal+2HPO₃⁻+2H⁺ (Equation 1)

The Co metal is thus deposited selectively on top of the exposed surfaces of the conductive material of the gouging feature 300. In implementations, the metal deposited by this reaction is one of Co, CoP, COWP, CoB, and COWB, depending on the composition of the plating bath solution.

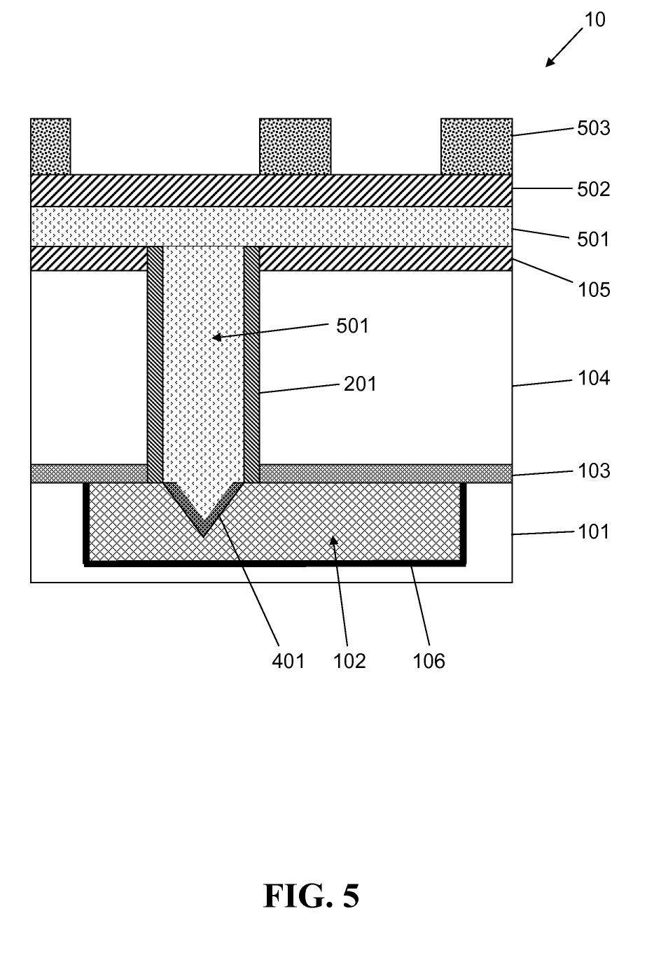

As depicted in FIG. 5, a planarization layer 501 is created by depositing a material in the contact via 107 and over the hardmask 105. The material may comprise, for example, conventional organic materials, antireflective coating materials, or spun-glass materials, and may have a thickness in the range of about 200 nm to 800 nm. The material of the planarization layer 501 may be deposited using any suitable conventional technique, such as, for example, spin-on coating, chemical solution deposition, etc.

The planarization layer 501 provides a substantially planar top surface for the application of a second hardmask 502 and a patterned photoresist 503. The second hardmask 502 may be formed using the same processing techniques, materials, and thickness as described above with respect to the first hardmask 105. The patterned photoresist 503 is formed by conventional deposition and lithography and contains openings that have the width of a wire feature (to be formed, as described below).

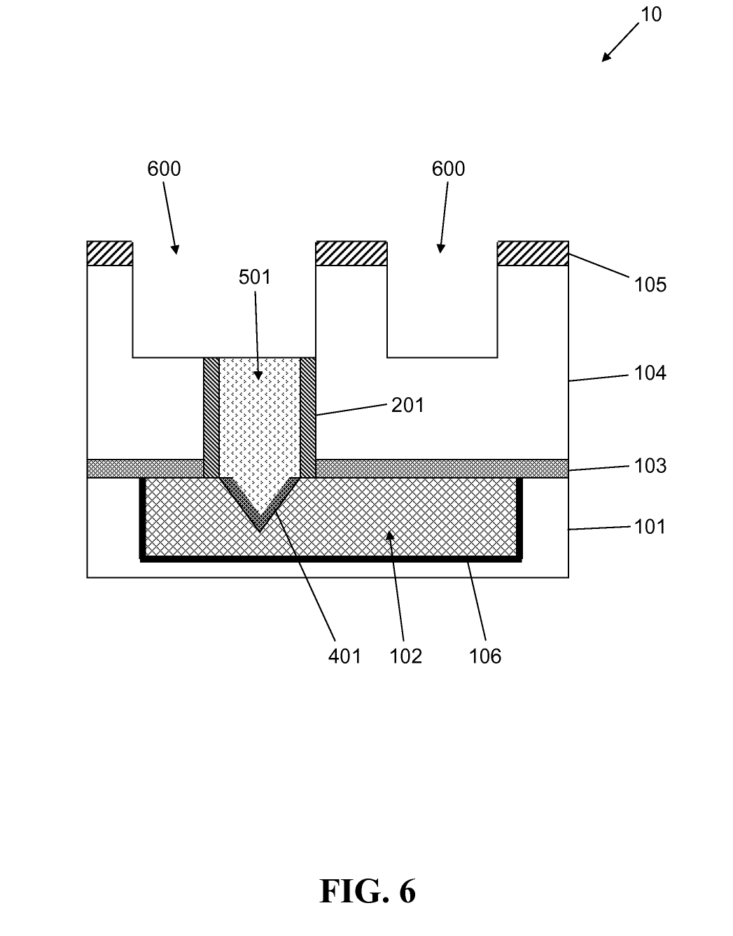

The structure shown in FIG. 5 is subject to one or more conventional etching process which result in the formation of the structure shown in FIG. 6. The one or more etchings form the wire features 600 in the second dielectric material 104. In embodiments, at least one wire feature 600 is located above and connected to the contact via 107, which remains filled by the material of the planarization layer 501. The one or more etching processes removes exposed portions of the second hard mask 502 and the corresponding underlying portions of the planarization layer 501, first hard mask 105, and second dielectric material 104. The patterned photoresist 503 and the patterned second hard mask 502 are typically consumed during the etching.

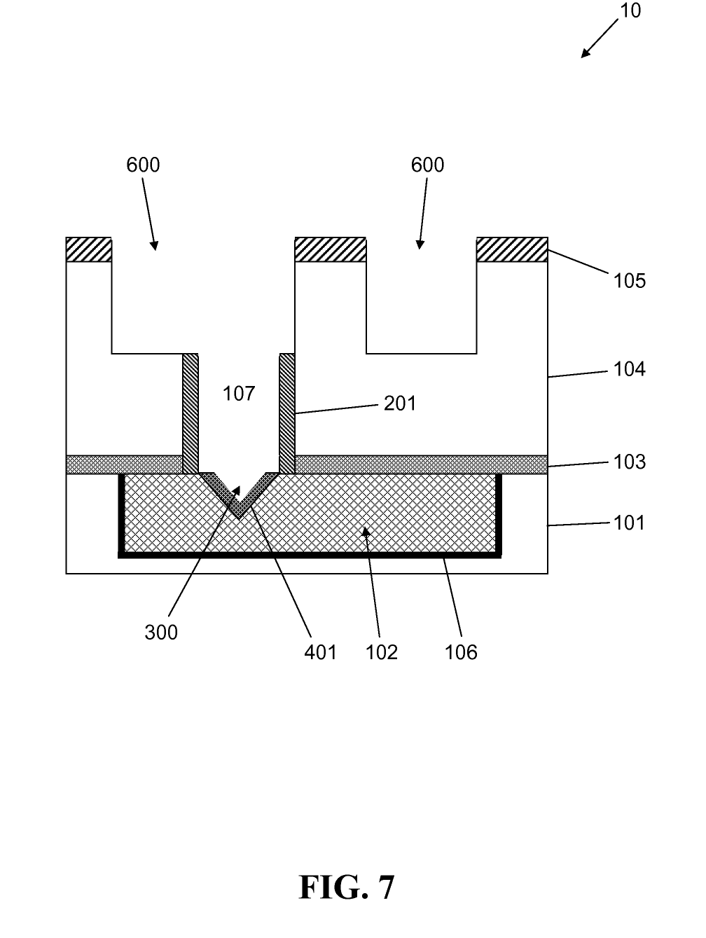

As shown in FIG. 7, the remainder of the material of the planarization layer 501 is stripped out of the contact via 107, including the gouging feature 300. The stripping may be performed by any suitable conventional stripping process, such as, for example, wet or dry stripping. The stripping process does not remove the liner 401.

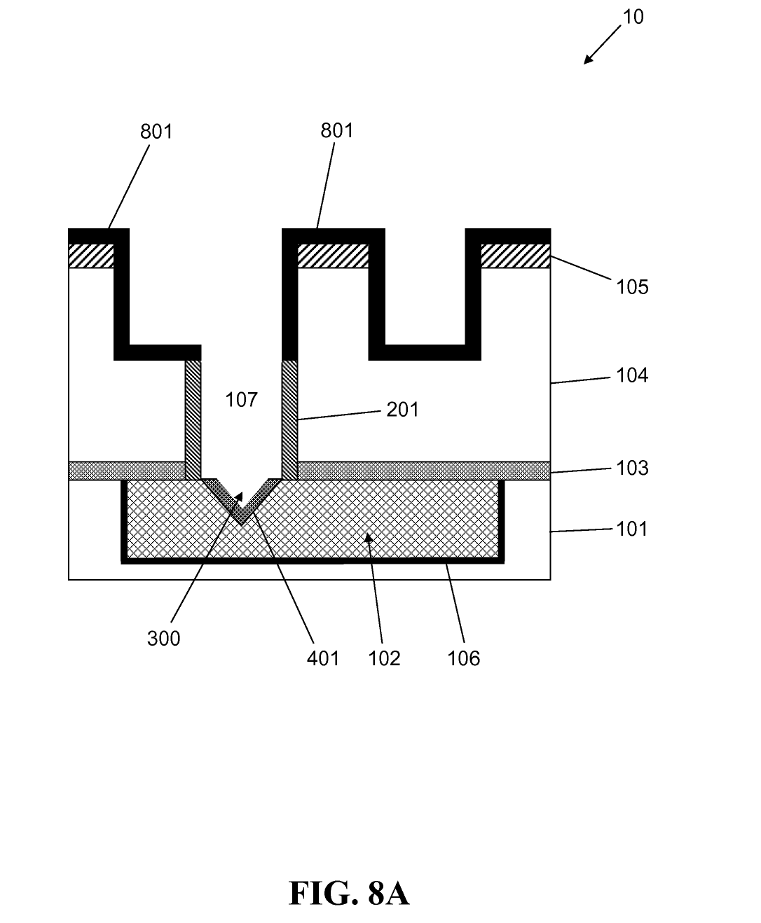

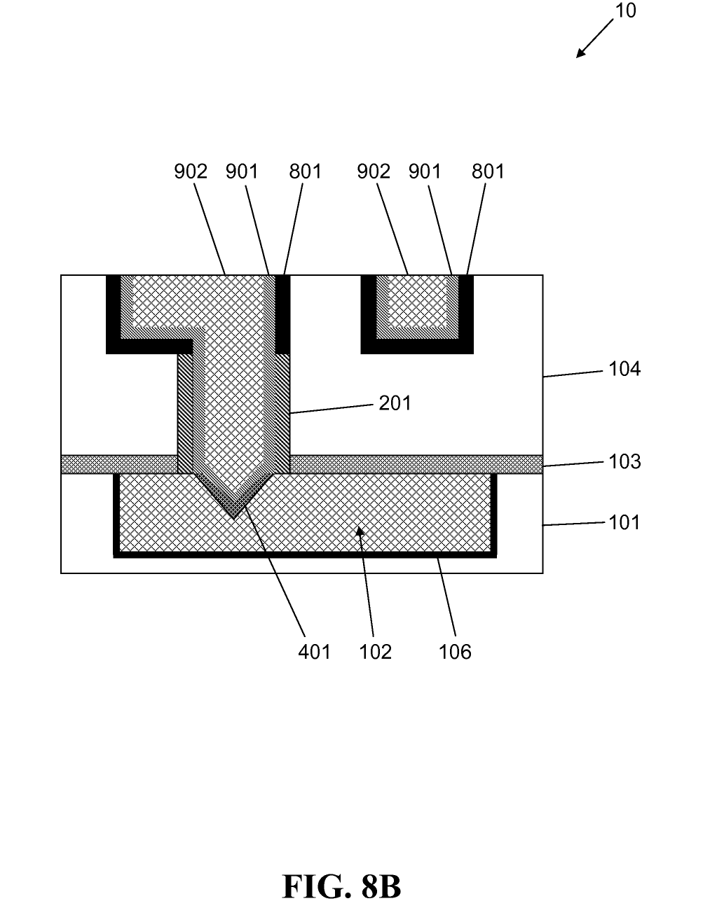

In embodiments, the liner 401 is left in place during filling of the contact via 107, gouging feature 300, and wire feature 600. For example, in a first embodiment shown in FIG. 8A, a diffusion barrier liner 801 is deposited over the exposed surfaces of the structure 10, except for the sidewalls of the contact via 107 and the liner 401 in the gouging feature 300. The diffusion barrier liner 801 may comprise, for example, Ta(N), Ti(N), W(N), Ru(N), or RuTa, and may have a thickness of about 2 nm to 60 nm, although other materials and thickness are contemplated for use with the invention. The material of the diffusion barrier liner 801 is applied by a non-directional deposition process that is capable of leaving the sidewalls of the contact via 107 and the liner 401 in the gouging feature 300 uncovered.

Still referring to the first embodiment, a copper seed layer 901 is deposited over the exposed surfaces of the contact via 107, gouging feature 300, and wire feature 600, as shown in FIG. 8B. The copper seed layer 901 may be deposited in any suitable conventional manner, such as, for example, PVD, AVD, etc., and may have a thickness of about 5 nm to 100 nm. Copper plating is used to fill the contact via 107, gouging feature 300, and wire feature 600 with copper, as is known to those of skill in the art. Finally, the top surface of the structure 10 is subjected to a chemical mechanical polish (CMP) process, resulting in the semiconductor structure shown in FIG. 8B.

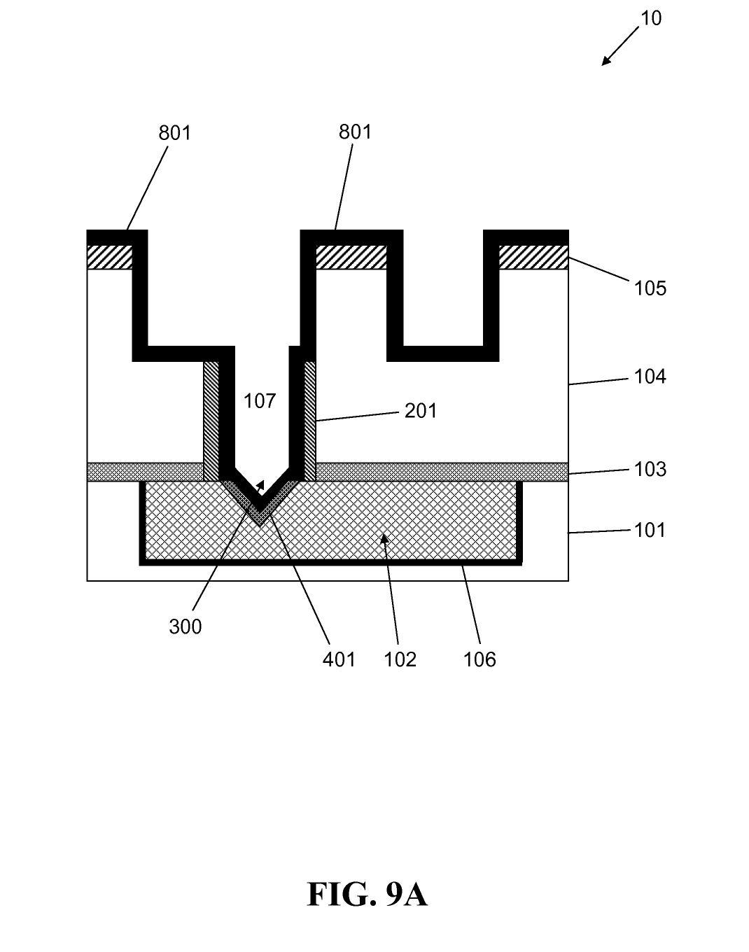

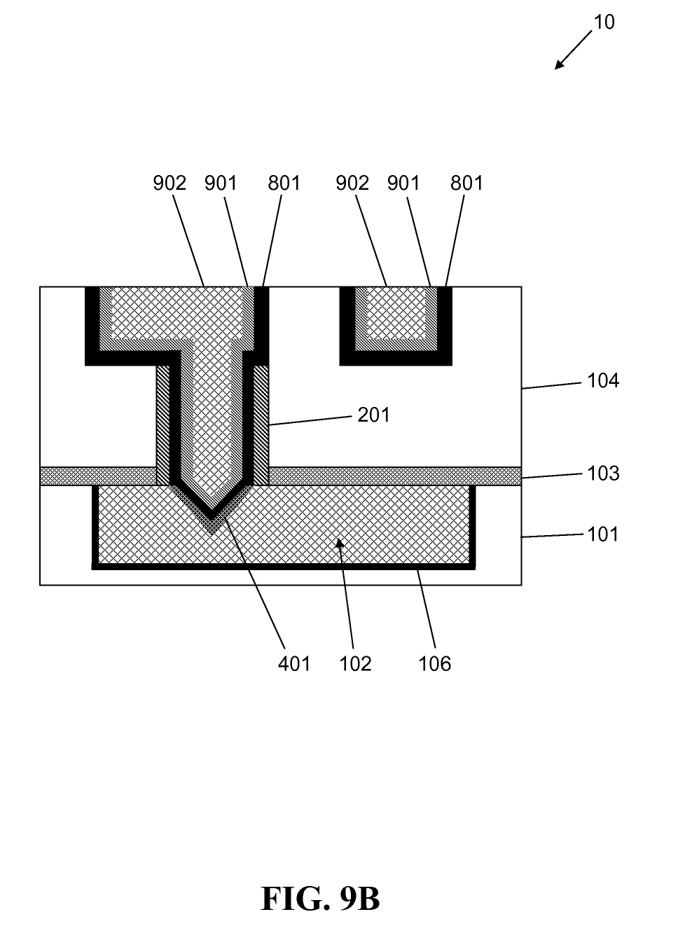

In a second embodiment shown in FIG. 9A, a diffusion barrier liner 801 is deposited over the exposed surfaces of the structure 10, including the sidewalls of the contact via 107 and the liner 401 in the gouging feature 300. The diffusion barrier liner 801 may comprise the same material and thickness range as described in references to FIG. 8A. The material of the diffusion barrier liner 801 is applied by a directional deposition process that covers the exposed surfaces of the structure 10.

Still referring to the second embodiment, a copper seed layer 901 is deposited over the exposed surfaces of the contact via 107, gouging feature 300, and wire feature 600, as shown in FIG. 9B. The copper seed layer 901 may be deposited in the same manner and thickness range as described with reference to FIG. 8B. Copper plating is used to fill the contact via 107, gouging feature 300, and wire feature 600 with copper material 902 in any suitable known fashion. Finally, the top surface of the structure 10 is subjected to a CMP process, resulting in the semiconductor structure shown in FIG. 9B.

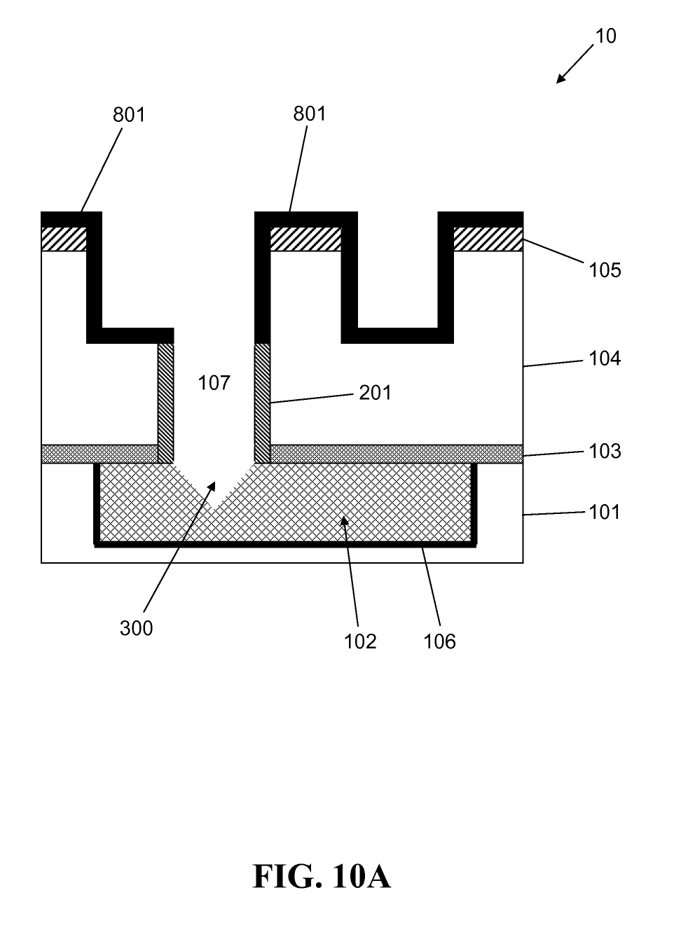

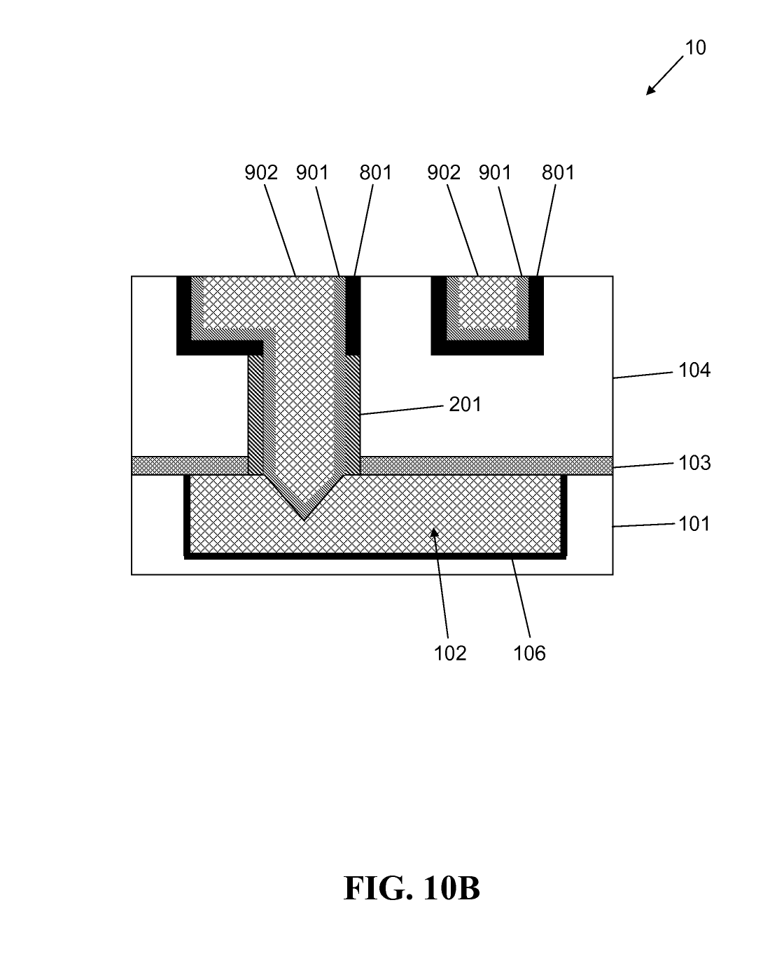

In other embodiments, the liner 401 is removed before subsequent filling of the contact via 107, gouging feature 300, and wire feature 600. For example, in a third embodiment shown in FIG. 10A, the liner 401 is removed by a sputtering process (such as that described with reference to FIG. 3) resulting in the exposure of the material of the interconnect feature 102 in the gouging feature 300. A diffusion barrier liner 801 is deposited over the exposed surfaces of the structure 10, except for the sidewalls of the contact via 107 and the exposed material in the gouging feature 300. The diffusion barrier liner 801 may comprise the same material and thickness range as described with reference to FIG. 8A. The material of the diffusion barrier liner 801 is applied by a non-directional deposition process that is capable of leaving the sidewalls of the contact via 107 and the exposed surfaces of the gouging feature 300 uncovered.

A copper seed layer 901 is deposited over the exposed surfaces of the contact via 107, gouging feature 300, and wire feature 600, as shown in FIG. 10B. The copper seed layer 901 may be deposited in the same manner and thickness range as described with reference to FIG. 8B. Copper plating is used to fill the contact via 107, gouging feature 300, and wire feature 600 with copper material 902 in any suitable known fashion. Finally, the top surface of the structure 10 is subjected to a CMP process, resulting in the semiconductor structure shown in FIG. 10B.

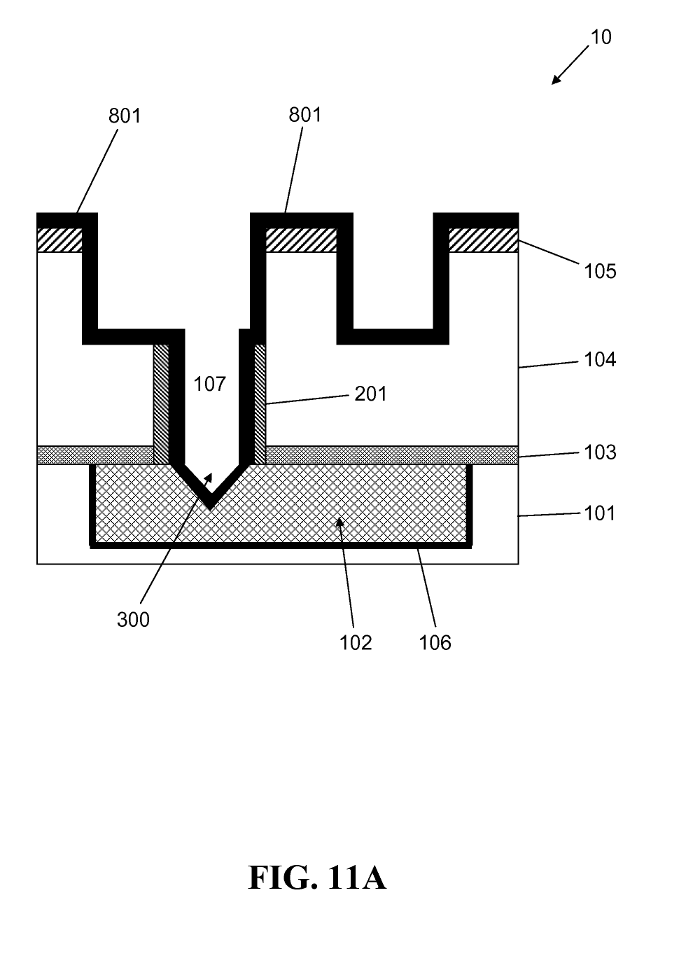

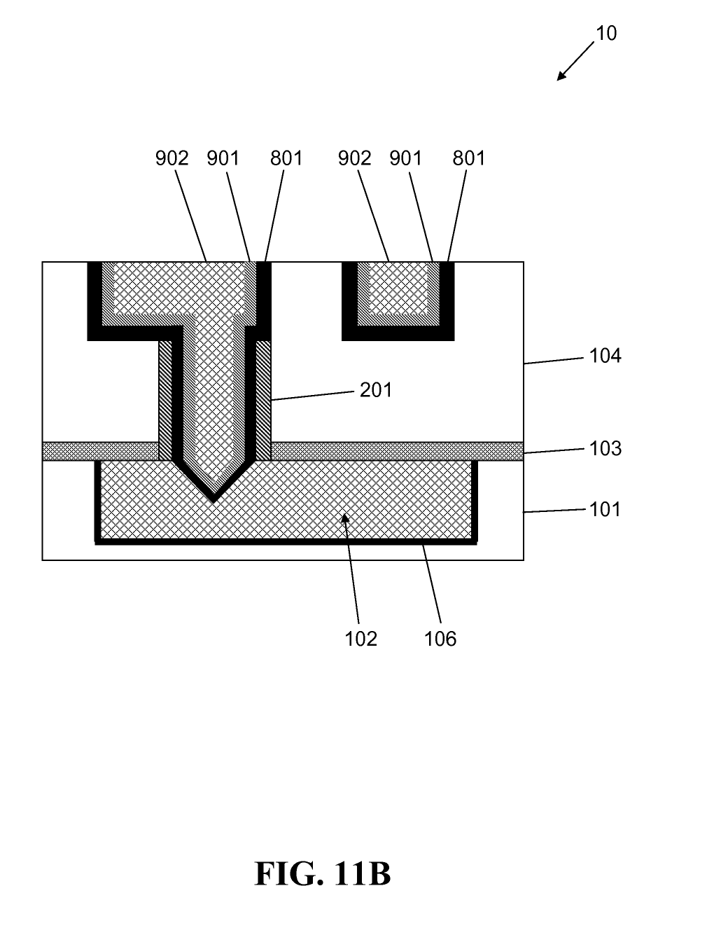

In a fourth embodiment shown in FIG. 11A, the liner 401 is removed by a sputtering process (such as that described with reference to FIG. 3) resulting in the exposure of the material of the interconnect feature 102 in the gouging feature 300. A diffusion barrier liner 801 is deposited over the exposed surfaces of the structure 10, including the sidewalls of the contact via 107 and the exposed material in the gouging feature 300. The diffusion barrier liner 801 may comprise the same material and thickness range as described with reference to FIG. 8A. The material of the diffusion barrier liner 801 is applied by a directional deposition process that covers the exposed surfaces of the structure 10.

Still referring to the fourth embodiment, a copper seed layer 901 is deposited over the exposed surfaces of the contact via 107, gouging feature 300, and wire feature 600, as shown in FIG. 11B. The copper seed layer 901 may be deposited in the same manner and thickness range as described above. Copper plating is used to fill the contact via 107, gouging feature 300, and wire feature 600 with copper material 902 in any suitable known fashion. The top surface of the structure 10 is subjected to a CMP process, resulting in the semiconductor structure shown in FIG. 11B.

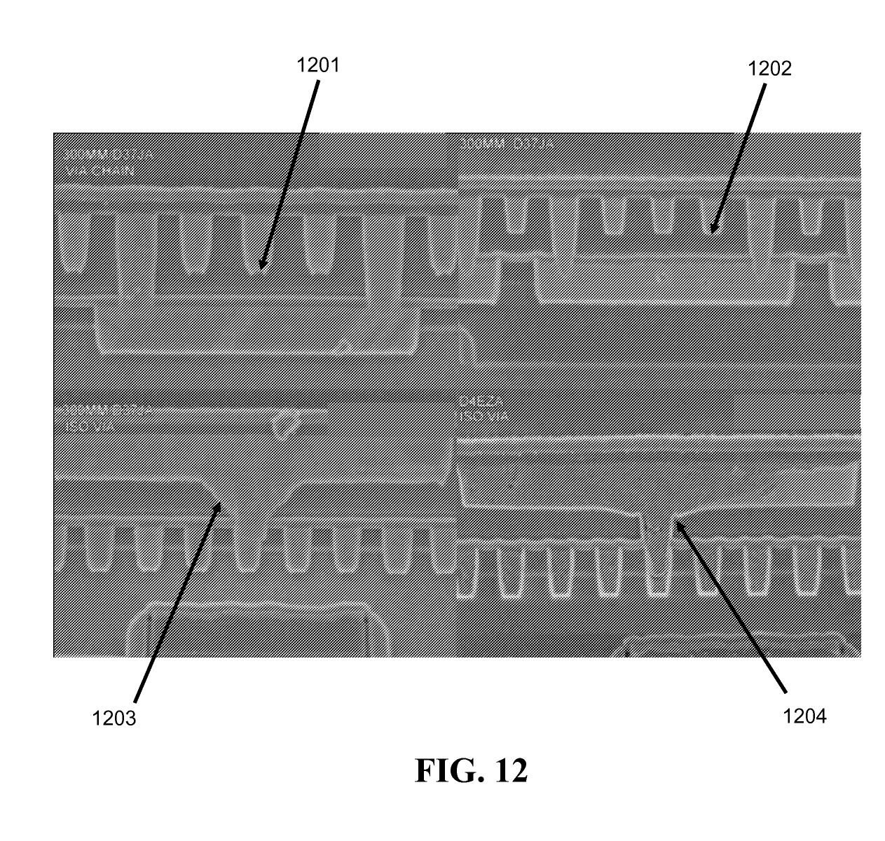

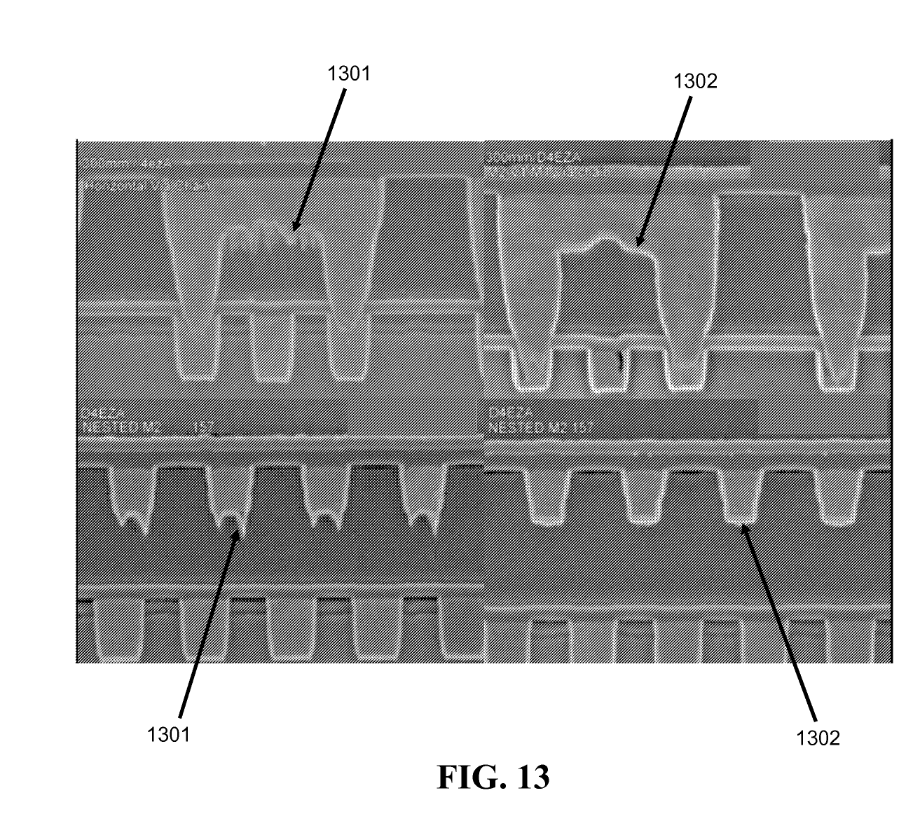

FIGS. 12 and 13 show scanning electron micrograph comparisons of known structures to structures produced according to implementations of the invention. For example, as shown in FIG. 12, roughening 1201 caused by sputtering damage is present at the base of features of the prior art structure. By comparison, features produced according to implementations of the invention have a smoother base 1202.

As further depicted in FIG. 12, a via feature produced according to a known structure has a shallow angle 1203 in the vicinity of the gouging feature due to damage caused by the sputtering process. However, a similar via feature of the structure produced according to an implementation of the invention has a sharper angle 1204.

FIG. 13 shows known features having rough bases 1301 due to sputtering damage. By comparison, features produced according to aspects of the invention have relatively smoother bases 1302. As such, implementations of the invention provide semiconductor structures with improved interconnect features (e.g., vias, wires, etc.), which result in the semiconductor structure having enhanced dielectric breakdown strength and/or electromigration resistance.

The semiconductor device as described above may be part of the design for an integrated circuit chip. In embodiments, the chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

While the invention has been described in terms of embodiments, those skilled in the art will recognize that the invention can be practiced with modifications and in the spirit and scope of the appended claims.

What is claimed:

1. A semiconductor structure, comprising:
an interconnect feature substantially filled with a conductive material and disposed within a first dielectric material;
a second dielectric material comprising a contact via over the interconnect feature;
a gouging feature in the conductive material and adjacent to the contact via; and
a first liner material deposited substantially only on surfaces of the conductive material in the gouging feature.

2. The semiconductor of claim 1, further comprising a second liner material on sidewalls of the contact via.

3. The semiconductor of claim 2, further comprising a wire feature in the second dielectric material and adjacent the contact via.

4. The semiconductor of claim 2, further comprising a third liner material on portions of the second dielectric material.

5. The semiconductor of claim 4, further comprising:
a seed layer on the first, second, and third liner materials; and
a second conductive material in the gouging feature and the contact via.

6. The semiconductor of claim 4, wherein the third liner material is further disposed on the second liner material and the first liner material.

7. The semiconductor of claim 6, further comprising:
a seed layer on the third liner material; and
a second conductive material in the gouging feature and the contact via.

8. The semiconductor of claim 1, wherein the first liner material comprises an alloy of Co and at least one of: W, P, B, Mo, and Re.

9. A semiconductor structure, comprising:
an interconnect feature substantially filled with a conductive material and disposed within a first dielectric material;
a second dielectric material comprising a contact via over the interconnect feature;
a gouging feature in the conductive material and adjacent to the contact via; and
a copper seed layer over the gouging feature.

10. The semiconductor structure of claim 9, further comprising:
a first liner material on portions of the second dielectric material in the contact via; and
a second liner material on other portions of the second dielectric material.

11. The semiconductor structure of claim 9, wherein:
the copper seed layer is disposed on the conductive material, the first liner material, and the second liner material, and
a second conductive material substantially fills the contact via and the gouging feature.

12. The semiconductor structure of claim 9, further comprising:
a first liner material on portions of the second dielectric material in the contact via; and
a second liner material on other portions of the second dielectric material, the first liner material, and the conductive material in the gouging feature.

13. The semiconductor structure of claim 12, wherein:
the copper seed layer is disposed on the second liner material, and
a second conductive material substantially fills the contact via and the gouging feature.

14. A method, comprising:
forming a dielectric material comprising a contact via over a conductive material of an interconnect feature;
forming a gouging feature in the conductive material and adjacent to the contact via; and
selectively depositing a first liner material substantially only on exposed surfaces of the conductive material in the gouging feature.

15. The method of claim 14, further comprising:
forming a second liner material on portions of the dielectric material in the contact via; and
forming a third liner material on other portions of the dielectric material.

16. The method of claim 15, further comprising:
forming a seed layer on the first, second, and third liner materials; and
substantially filling the gouging feature and contact via with a second conductive material.

17. The method of claim 15, further comprising:
forming a seed layer substantially only on the third liner material; and
substantially filling the gouging feature and contact via with a second conductive material.

18. The method of claim 14, further comprising:
forming a second liner material on portions of the dielectric material in the contact via;
forming a third liner material on other portions of the dielectric material;
removing the first liner material;
forming a seed layer on the second liner material, the third liner material, and the conductive material in the gouging feature; and
substantially filling the gouging feature and contact via with a second conductive material.

19. The method of claim 14, further comprising:
forming a second liner material on portions of the dielectric material in the contact via;
removing the first liner material;
forming a third liner material on other portions of the dielectric material, the second liner material, and the conductive material in the gouging feature;
forming a seed layer substantially only on the third liner material; and
substantially filling the gouging feature and contact via with a second conductive material.

20. The method of claim 14, wherein the forming a gouging feature comprises gaseous sputtering with one of Ar, He, Ne, Xe, N₂, H₂, NH₃, N₂H₂, or mixtures thereof.
